(19) United States
(12) Patent Application Publication
(10) Pub. No.: US 2025/0202472 A1
(43) Pub. Date: Jun. 19, 2025

(54) INTEGRATED CIRCUIT COMPRISING A CIRCUIT FOR MATCHING THE VOLTAGE SUPPLIED TO THE GATE OF A POWER TRANSISTOR

(71) Applicant: Wise-Integration, Hyeres (FR)

(72) Inventors: Dominique Bergogne, Saint Didier En Velay (FR); Sebastian Gaviria Duque, Grenoble (FR)

(21) Appl. No.: 18/848,970

(22) PCT Filed: Mar. 28, 2023
(86) PCT No.: PCT/FR2023/050441

§ 371 Date: Sep. 20, 2024

(30) Foreign Application Priority Data
Mar. 31, 2022 (FR) FR2202957

(51) Int. Cl. H03K 17/10

(52) U.S. Cl. CPC H03K 17/102

(57) ABSTRACT

The invention relates to an integrated circuit comprising: an enhanced-mode power transistor, and a circuit for adapting the voltage supplied to the gate of said enhanced-mode power transistor, said adaptation circuit comprising at least one branch connected between an input terminal (INPUT) and the second terminal (SOURCE), said branch comprising a depletion-mode head transistor, a depletion-mode tail transistor connected to a first dipole, a connecting quadrupole and an enhanced-mode base transistor, the source of which is connected to the second terminal (SOURCE), and the gate of which is connected to its drain, said drain being connected to a second dipole, said control circuit being connected, by the source of the head transistor, to the gate of the power transistor.

### TECHNICAL FIELD

The invention relates to the field of power electronics.

The invention relates, in particular, to a circuit for adapting the voltage supplied to the gate of power transistors.

The invention advantageously makes it possible to control the gate of power transistors with higher voltage levels than in the prior art, without damaging the power transistors.

The invention further proposes a more robust and compact adaptation circuit than the circuits of the prior art.

### STATE OF THE ART

Power electronics is a branch of electronics dedicated to high-power energy transfers, for which it is important to minimise energy losses. It is mainly based on the use of controlled power switches. To do this, numerous silicon technology switches (IGBT, MOSFET), as well as wide-bandgap semiconductor components (SiC, GaN) can be used. Transistors can be controlled by a control circuit, called a “driver”. This control circuit aims to control the charge and/or the discharge of the gate of the power component in order to enable changes in states of the power transistor.

Generally, the gate of the transistors is limited in the voltage values that it can have applied without being damaged. Typically, according to GaN transistor models, this voltage can be, as a maximum, 3, 6 or 9V.

Drivers, themselves, can supply voltages of between 6 and 20V. In order to adapt the voltage supplied by the driver, an adaptation circuit can be inserted between the driver and the gate of the power transistor.

To do this, it is possible to use circuits formed of discrete components, such as represented in FIG. 1.

Typically, the adaptation circuit 200 of the prior art receives as input INPUT, a pulse-width-modulated signal, alternating between a high state and a low state, also called PWM signal. The input INPUT is connected to a first interconnecting point A1 of three branches of the adaptation circuit 200.

A first branch comprises a resistor R4 connected in series with the cathode of a Schottky diode D4, the anode of which is connected to a second interconnecting point A2.

A second branch, mounted in parallel to the first branch, comprises a resistor R3.

The third branch comprises, among others, two Schottky diodes D2, D3. The first Schottky diode D2 is connected to the first interconnecting point A1 by its cathode, while the second diode D3 is connected to the first interconnecting point A1 by its anode. The cathode of the second Schottky diode D3 is connected, on the one hand, to a capacitor C1 and on the other hand, to the cathode of a Zener diode D1, the capacitor C1 and the Zener diode D1 being connected in parallel. The anode of the first diode D2 is connected to a resistor R2, the other terminal of which is connected, on the one hand, to the ground, and on the other hand, to the anode of the Zener diode D1 and to the second terminal of the capacitor C1.

The adaptation circuit 200 supplies the gate of the power transistor P2.

Such a circuit has the disadvantage of comprising a large number of components, and consequently, occupying a significant surface area, which does not make it possible to integrate the circuit in small spaces.

Another solution of the prior art, consists of using an integrated circuit, as that of patent US 2020/0357906 illustrated in FIG. 2.

The integrated circuit 300 also receives, as input, a pulse-width-modulated signal. The input is connected to the drain of a transistor T1. The gate of the transistor T1 is connected to the cathode of a Zener diode D7, the anode of which is connected to the ground. A resistor R7 is connected between the drain and the gate of the transistor T1. The source of the transistor T1 is connected to the gate of a power transistor, the voltage of which is sought to be regulated.

This circuit is commonly called a “clamp circuit”. It makes it possible, thanks to the presence of the Zener diode D7, to limit the voltage delivered to the gate of the power transistor, not represented in the figure, and connected to the point called “clamped signal”.

Although this circuit is more compact than that of FIG. 1, it is very sensitive to variations in temperature and to variations in the manufacturing parameters of transistors, also called “process corners”.

The problem that the invention proposes to resolve, is to supply an adaptation circuit which is more compact than the circuits of the prior art, and the sensitivity of which to variations in temperature and to variations in the manufacturing parameters of transistors is limited.

### SUMMARY OF THE INVENTION

To solve this problem, the Applicant has developed an integrated circuit comprising:
an enhanced-mode power transistor, the drain of which is connected to a first terminal of the integrated circuit, and the source of which is connected to a second terminal of the integrated circuit, and
a circuit for adapting the voltage supplied to the gate of an enhanced-mode power transistor comprising at least one branch connected between an input adapted to receive a signal which could adopt a low state and a high state, and the second terminal.

This branch comprises:
a depletion-mode head transistor, the drain of which is connected to the input,
a depletion-mode tail transistor, the source of which is connected to a terminal of a first dipole, and the gate of which is connected to the second terminal of the first dipole,
a connecting (or linking) quadrupole, the first terminal of which is connected to the gate of the head transistor, the second terminal of which is connected to the source of the head transistor, the third terminal of which is connected to the source of the tail transistor, the third terminal of which is connected to the source of the tail transistor and the fourth terminal of which is connected to the drain of the tail transistor, and
an enhanced-mode base (or feet) transistor, the source of which is connected to the second terminal, and the gate of which is connected to its drain, said drain being connected to a second terminal of a second dipole, the first terminal of which is connected to the second terminal of the first dipole.

Said adaptation circuit is connected, by the source of the head transistor, to the gate of the power transistor.

According to the invention, a signal which could adopt a low state and a high state is, for example, a pulse-width-modulated signal.

Such an adaptation circuit has very few components, compared with the prior art of FIG. 1. It is therefore easier to implement in integrated circuits. In addition, less interference, linked to the interactions of components with one another, appear on the control signal of the power transistor, due to the limited number of components. Furthermore, the circuit can be qualified as quasi-passive, in this sense, that it only comprises one input connected to a driver and an output connected to the gate of a power transistor, and that it does not require any energy source, other than that supplied by the driver to adapt the voltage.

In addition, it is known that depletion-mode transistors have a negative threshold voltage, and enhanced-mode transistors have a positive threshold voltage.

By observing the threshold voltages of enhanced-mode and depletion-mode transistors during variations of manufacturing parameters, it is sometimes possible to compensate for the effects of these variations on the performance of the circuit using its transistors.

Thus, in the circuit of the invention, an enhanced-mode transistor can compensate for a pair of depletion-mode transistors when the lower part and the upper part of the circuit are combined.

The direct consequence is that the fluctuations linked to the variations in temperature and to the variations in method for manufacturing a given transistor are compensated for by the presence of other transistors of the circuit.

The circuit is therefore more robust than the circuits of the prior art.

According to a first embodiment, the connecting quadrupole mentioned above is constituted of two short-circuits respectively connecting the first and third terminals and the second and fourth terminals.

Advantageously, the second dipole is thus a short-circuit.

This embodiment is the simplest. The circuit only comprises two depletion-mode transistors, a enhanced-mode transistor and a dipole, that is four components in total. Such a circuit is therefore particularly easy to implement and to integrate in integrated circuits.

The number of enhanced-mode transistors and the number of depletion-mode transistors is chosen according to the maximum voltage value that it sought to be applied to the gate of the enhanced-mode power transistor.

Thus, the adaptation circuit of this first embodiment delivers a maximum voltage of 3V.

According to a second embodiment, the connecting quadrupole comprises two depletion-mode transistors: a high transistor and a low transistor, the source of the high transistor being connected to the drain of the low transistor and to the first terminal of the connecting quadrupole, the drain of the high transistor being connected to the second terminal of the connecting quadrupole, the gate of the low transistor being connected to the third terminal of the connecting quadrupole and the gate of the high transistor and the source of the low transistor being connected to the fourth terminal of the connecting quadrupole.

Advantageously, the second dipole thus comprises an enhanced-mode transistor, the source of which is connected to the second terminal of the second dipole and the gate of which is connected to its drain, said drain being connected to the first terminal of the second dipole.

In this embodiment, the circuit thus comprises two enhanced-mode transistors, the threshold voltages of which being compensated for with the two pairs of depletion-mode transistors.

The adaptation circuit of this second embodiment thus delivers a maximum voltage of 6V.

According to a third embodiment, the connecting quadrupole is constituted of n elementary quadrupoles, with n>1, each elementary quadrupole comprising two depletion-mode transistors: a high transistor and a low transistor, the source of the high transistor being connected to the drain of the low transistor and to a first terminal of the elementary quadrupole, the drain of the high transistor being connected to a second terminal of the elementary quadrupole, the gate of the low transistor being connected to a third terminal of the elementary quadrupole and the gate of the high transistor and the source of the low transistor being connected to a fourth terminal of the elementary quadrupole; the elementary quadrupoles being connected in series, with two consecutive elementary quadrupoles connected such that the first terminal of the elementary quadrupole is connected to the third terminal of the elementary quadrupole and the second terminal of the elementary quadrupole is connected to the fourth terminal of the elementary quadrupole; the first and the second terminals of the elementary quadrupole forming the first and the second terminals of the connecting quadrupole and the third and the fourth terminals of the elementary quadrupole forming the third and the fourth terminals.

Advantageously, the second dipole thus comprises n enhanced-mode transistors, each of said transistors having its gate connected to its drain, said transistors being connected in series, two consecutive transistors being connected by the source of one and the drain of the other and, the drain of the first transistor forming the first terminal of the second dipole and the source of the last transistor forming the second terminal of the second dipole.

According to the embodiments, the first dipole can, for example, be an enhanced-mode transistor, the gate of which is connected to its drain. The transistor thus behaves like a diode. Preferably, the first dipole is a resistor which makes it possible to better compensate for the variations within the circuit. The sizing of the transistor or the value of the resistor in principle has no significant impact on the value of the voltage reference.

However, the sizing of these components can be adapted in order to limit the energy consumption of the adaptation circuit.

The adaptation circuit of this third embodiment thus delivers a maximum voltage of 3V multiplied by n.

In order to increase the value of the current transmitted to the power transistor, it is possible to connect several branches such as described above in parallel.

The adaptation circuit thus comprises m branches connected in parallel, each branch being connected by the source of its head transistor, to the gate of the power transistor. The current available at the output is thus increased by a ratio m, while keeping the performances of the original branch.

### DESCRIPTION OF THE FIGURES

The way in which to achieve the invention, as well as the advantages which arise from it, will emerge from the description of the embodiments below, in support of the accompanying figures, in which:

FIG. 1 is an electric diagram of an adaptation circuit of the prior art comprising discrete components,

FIG. 2 is an electric diagram of another adaptation circuit of the prior art, which can be achieved in an integrated circuit,

FIG. 3 is an electric diagram of the adaptation circuit of the invention according to a first embodiment,

FIG. 4 is an electric diagram of a variant of the embodiment of FIG. 3,

FIG. 5 is an electric diagram of the adaptation circuit of the invention according to a second embodiment,

FIG. 6 is an electric diagram of the adaptation circuit of the invention according to a third embodiment,

FIG. 7 is an electric diagram of the adaptation circuit of the invention according to a fourth embodiment,

FIG. 8 is an electric diagram of the adaptation circuit of the invention according to a fifth embodiment,

FIG. 9 is an electric diagram of the adaptation circuit of the invention according to a sixth embodiment, and

FIG. 10 is a comparative graph between the input signal and the output signal of the circuit of the invention for different transistors, the manufacturing process of which varies.

FIG. 11 is a graph illustrating the behaviour of the amplitude of the signal supplied to the gate of the power transistor according to the input voltage, under three conditions of the process corner.

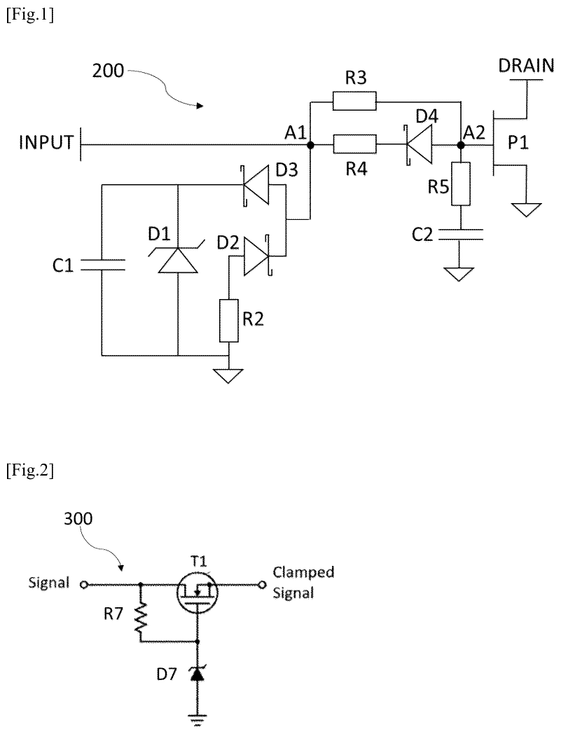

### DETAILED DESCRIPTION OF THE EMBODIMENTS

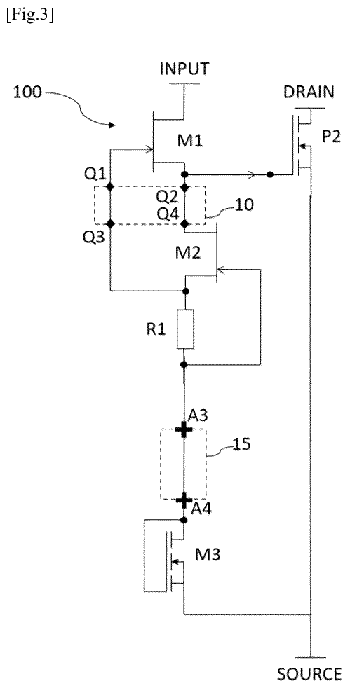

Such as illustrated in FIGS. 3 to 9, the integrated circuit of the invention comprises an adaptation circuit connected to the gate of an enhanced-mode power transistor P2-P8. The integrated circuit has three terminals. An input terminal INPUT, a first terminal DRAIN connected to the drain of the enhanced-mode power transistor P2-P8, and a second terminal SOURCE connected to the source of the enhanced-mode power transistor P2-P8.

The adaptation circuit comprises at least one branch 101-108. Each branch comprises a head transistor M1, M11, M21, M31, M41, M51, M61, M71, the drain of which is connected to the input terminal INPUT intended to receive a pulse-width-modulated signal, alternating between a high state and a low state. This signal is, for example, supplied by a control circuit or “driver”. The input signal INPUT can, for example, adopt a high state of between 8 and 12V and a low state equal to 0V.

The source of the head transistor M1, M11, M21, M31, M41, M51, M61, M71 is connected to the gate of the enhanced-mode power transistor P2-P8.

Each branch 101-108 of the adaptation circuit of the invention also comprises a tail transistor M2, M14, M26, M36, M44, M54, M64, M74.

The two head M1, M11, M21, M31, M41, M51, M61, M71 and tail M2, M14, M26, M36, M44, M54, M64, M74 transistors are connected to one another by a connecting quadrupole 10, 20, 30, 40.

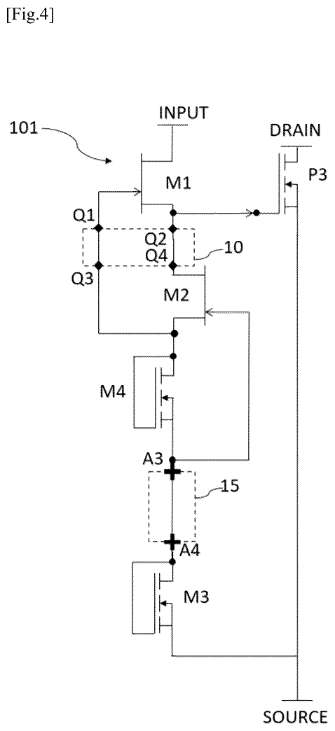

In the first embodiment of FIGS. 3 and 4, the connecting quadrupole 10 corresponds to two short-circuits. A first short-circuit connects the terminals Q1 and Q3 of the connecting quadrupole 10 and the second short-circuit connects the terminals Q2 and Q4 of the connecting quadrupole 10.

Thus, the head transistor M1 is connected, by its source, to the drain of the tail transistor M2 by way of the short-circuit connecting the terminals Q2 and Q4. In addition, the source of the tail transistor M2 is connected to the gate of the head transistor M1 by way of the short-circuit connecting the terminals Q1 and Q3.

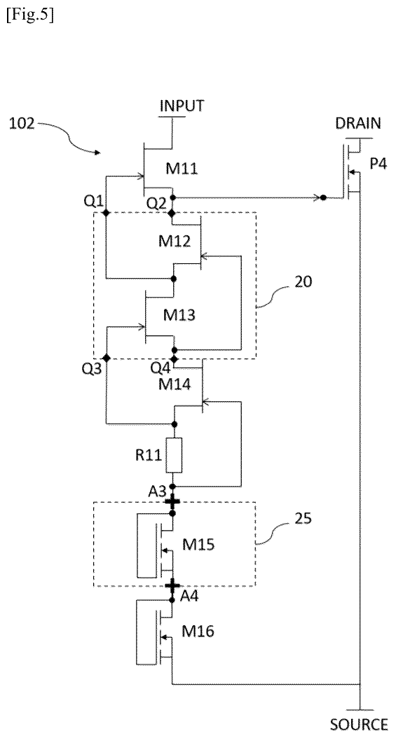

In the second embodiment of FIG. 5, the connecting quadrupole 20 comprises two depletion-mode transistors M12, M13 in series: a high transistor M12 and a low transistor M13. The source of the high transistor M12 is connected to the drain of the low transistor M13 and to the first terminal Q1 of the connecting quadrupole 20. The first terminal Q1 is also connected to the gate of the head transistor M11. The drain of the high transistor M12 is connected to the second terminal Q2 of the connecting quadrupole 20. The second terminal Q2 is also connected to the source of the head transistor M11. The gate of the low transistor M13 being connected to the third terminal Q3 of the connecting quadrupole 20. The third terminal Q3 is also connected to the source of the tail transistor M14. Finally, the gate of the high transistor M12 and the source of the low transistor M13 are connected to the fourth terminal Q4 of the connecting quadrupole 20, the latter also being connected to the drain of the tail transistor M14.

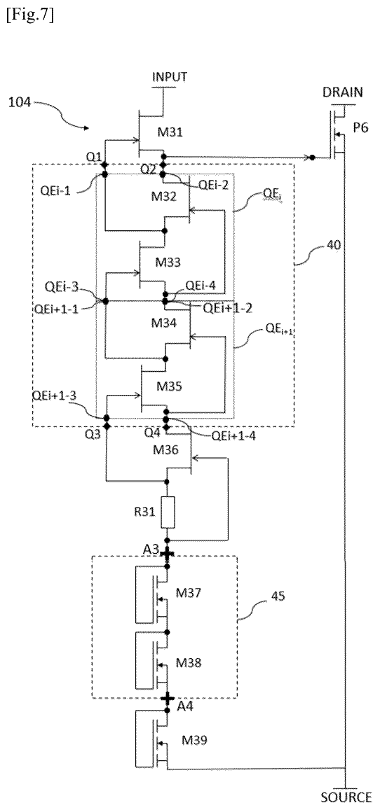

In the fourth embodiment of FIG. 7, the connecting quadrupole 30 is constituted of two elementary quadrupoles QEi, QEi+1 connected in series, i.e. that the third terminal QEi-3 of the first elementary quadrupole QEi is connected to the first terminal QEi+1-1 of the second elementary quadrupole QEi+1 and the fourth terminal QEi-4 of the first elementary quadrupole QEi is connected to the second terminal QEi+1-2 of the second elementary quadrupole QEi+1. Each elementary quadrupole QEi, QEi+1 comprises two depletion-mode transistors M32-M35: a high transistor M32, M34 and a low transistor M33, M35. The source of each high transistor M32, M34 is connected to the drain of each low transistor M33, M35 and to a first terminal QEi-1, QEi+1-1 of each elementary quadrupole QEi, QEi+1. The drain of each high transistor M32, M34 is connected to a second terminal QEi-2, QEi+1-2 of each elementary quadrupole QEi, QEi+1, the gate of each low transistor M33, M35 is connected to a third terminal QEi-3, QEi+1-3 of each elementary quadrupole QEi, QEi+1 and the gate of each high transistor M32, M34 and the source of each low transistor M33, M35 are connected to a fourth terminal QEi-4, QEi+1-4 of each elementary quadrupole QEi, QEi+1. The terminals QEi-1 and QEi-2 respectively form the terminals Q1 and Q2 of the connecting quadrupole 30 and the terminals QEi+1-3 and QEi+1-4 respectively form the terminals Q3 and Q4 of the connecting quadrupole 30.

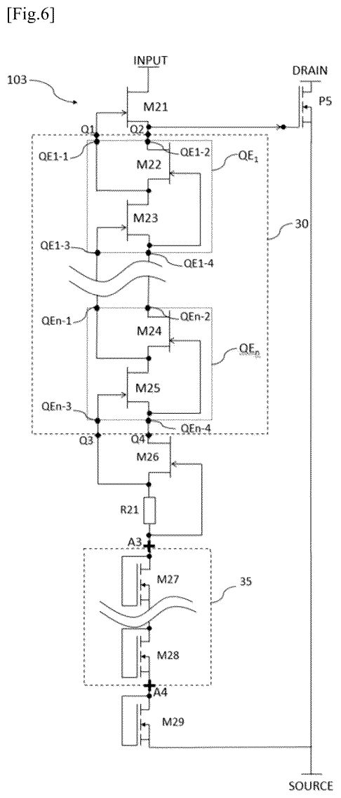

In the third embodiment of FIG. 6, the connecting quadrupole 40 is constituted of n elementary quadrupoles QE1-QEn, with n>1. Each elementary quadrupole comprises two depletion-mode transistors: a high transistor M22, M24 and a low transistor M23, M25, connected in the same way as for the elementary quadrupoles QEi, QEi+1 described in reference to FIG. 5. The elementary quadrupoles QE1-QEn are connected in series, with two consecutive elementary quadrupoles QEi, QEi+1 connected such that the first terminal QEi+1-1 of the elementary quadrupole QEi+1 is connected to the third terminal QEi-3 of the elementary quadrupole QEi and the second terminal QEi+1-2 of the elementary quadrupole QEi+1 is connected to the fourth terminal QEi-4 of the elementary quadrupole QEi. The first and the second terminal QE1-1, QE1-2 of the elementary quadrupole QE1 form the first and the second terminal Q1, Q2 of the connecting quadrupole 40 and the third and the fourth terminal QEn-3, QEn-4 of the elementary quadrupole QEn form the third and the fourth terminal Q3, Q4 of the connecting quadrupole 40.

The head and tail transistors are depletion-mode transistors. They can belong to the category of GaN transistors or of MOS transistors.

The tail transistor M2, M14, M26, M36, M44, M54, M64, M74 is connected by its source to a terminal of a first dipole. The gate of the tail transistor M2, M14, M26, M36, M44, M54, M64, M74 is connected to the second terminal of the first dipole. The first dipole can, for example, be a resistor R1, R11, R21, R31, R41, R51, R61, R71 such as illustrated in FIGS. 3 and 5-9, or also a diode. For example, the first dipole is an enhanced-mode transistor M4, mounted as a diode, i.e. that its gate is connected to its drain, such as illustrated in FIG. 4.

The second terminal of the first dipole is connected in series with a second dipole 15, 25, 35, 45.

In the first embodiment of FIGS. 3 and 4, the second dipole 15 corresponds to a short-circuit.

In the second embodiment of FIG. 5, the second dipole 25 comprises an enhanced-mode transistor M15, the source of which is connected to the second terminal of the second dipole 25, and the gate of which is connected to its drain. The latter is also connected to the first terminal of the second dipole 25.

In the fourth embodiment of FIG. 7, the second dipole 35 comprises 2 enhanced-mode transistors M37, M38. Each transistor M37, M38 has its gate connected to its drain. The transistors M37, M38 are connected in series, i.e. the source of the first transistor M37 is connected to the drain of the second transistor M38. The drain of the first transistor M37 thus forms the first terminal A3 of the second dipole 45 and the source of the second transistor M38 forms the second terminal A4 of the second dipole 45.

In the third embodiment of FIG. 6, the second dipole 35 comprises n enhanced-mode transistors M27, M28. Each transistor M27, M28 has its gate connected to its drain. The transistors M27, M28 are connected in series, i.e. that two consecutive transistors M27, M28 are connected by the source of one and the drain of the other. The drain of the first transistor M27 thus forms the first terminal A3 of the second dipole 35 and the source of the last transistor M28 forms the second terminal A4 of the second dipole 35.

The second terminal of the second dipole 15, 25, 35, 45 is connected to a non-linear component. In practice, the non-linear component is a base transistor M3, M16, M29, M39. The base transistor M3, M29, M39 is advantageously an enhanced-mode transistor, the gate of which is connected to its drain. The base transistor M3, M29, M39, M46, M56, M66, M76 is connected to the second terminal SOURCE, which is itself generally connected to the ground, by its source.

The maximum voltage value supplied to the gate of the power transistor P2-P8 is determined by the number of enhanced-mode transistors M3, M15, M16, M27-M29, M37-M39, M45, M46, M55, M56 of the circuit.

Thus, the first embodiment comprises one single enhanced-mode transistor M3 and makes it possible to limit the voltage supplied to the gate of the power transistor P2 to a value substantially equal to 3V. The second embodiment comprises two enhanced-mode transistors M15, M16 and makes it possible to limit the voltage supplied to the gate of the power transistor P4 to a value substantially equal to 6V. The fourth embodiment comprises three enhanced-mode transistors M37-M39 and makes it possible to limit the voltage supplied to the gate of the power transistor P6 to a value substantially equal to 9V. The third embodiment comprises n enhanced-mode transistors M37-M39 and makes it possible to limit the voltage supplied to the gate of the power transistor P5 to a value substantially equal to n times 3V.

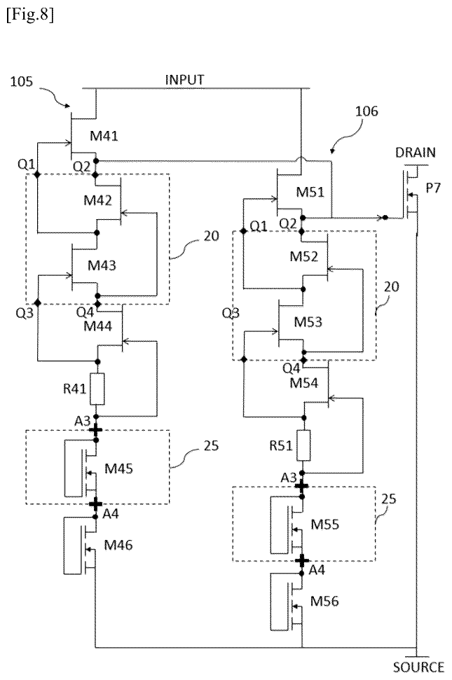

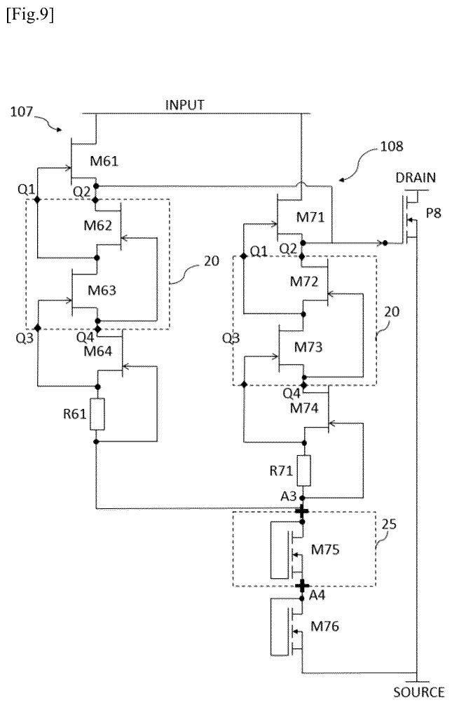

According to the fifth and sixth embodiments illustrated in FIGS. 8 and 9, it is possible to mount two identical branches 101-108 in parallel in order to increase the current of the signal supplied to the gate of the power transistor P2-P8, while preserving an identical voltage. Thus, the fifth and sixth embodiment comprise two branches 105-108 each comprising two enhanced-mode transistors M45, M46, M65, M66 and make it possible to limit the voltage supplied to the gate of the power transistor P7, P to a value substantially equal to 6V.

Thus, in the case of a circuit only comprising one branch, the current circulating in the circuit from the input INPUT to the gate of the enhanced-mode power transistor P2-P8 is about 1 A.

When several branches are connected in parallel, the current can reach several Amperes. The invention is therefore well adapted to a large range of power transistors.

To do this, such as illustrated in FIG. 8, the branches 105 and 106 are connected in parallel between the input INPUT and the second terminal SOURCE. The branch 105 is connected to the branch 106 by the source of its head transistor M41, which is connected to the source of the head transistor M51 of the branch 106. The sources of the two head transistors M41, M51 are thus connected to the gate of the power transistor P7.

In a variant, such as illustrated in FIG. 9, it is possible to pool the lower part of the adaptation circuit, comprising the enhanced-mode transistors M75, M76. Thus, the branches 105 and 106 are connected in parallel between the input INPUT and the second terminal of the first dipole R71.

The adaptation circuit obtained is therefore not very sensitive to the fluctuations of the supply voltage, of the temperature and of the variations in transistor manufacturing method.

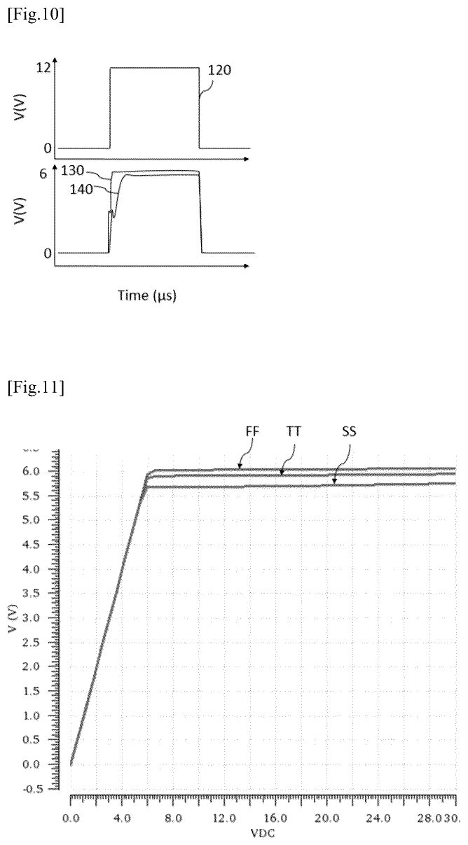

Indeed, the Applicant has performed digital simulations, the results of which are illustrated in FIGS. 10 and 11. Thus, for an input signal 120 having a high state equal to 12V and a low state equal to 0V, the signal supplied to the gate of the power transistor P2-P8 varies very little according to the transistor manufacturing process. In the worst case, i.e. for slow-slow (SS) transistors, the signal 140 has a slight delay increasing, but which remains absolutely satisfactory. For all the other combinations of transistors, the signal 130 is faithfully reproduced and has a low state at 0V and a high state at 6V.

FIG. 11 illustrates the behaviour of the signal (referenced V(V)) supplied to the gate of the power transistor according to the input voltage INPUT (referenced VDC), obtained via the process corner traditionally used in digital simulation to examine the behaviour of a circuit by considering the variations linked to the manufacturing method. Thus, the curves FF and SS correspond to the simulations at the two extreme “corners” of the “process corner”, namely fast-fast and slow-slow respectively, and the curve TT corresponds to the simulation to a nominal or typical condition. It is thus noted, that the voltage V(V) remains substantially constant under the conditions in question.

1. Integrated circuit comprising:
an enhanced-mode power transistor, the drain of which is connected to a first terminal of the integrated circuit, and the source of which is connected to a second terminal of the integrated circuit,
a circuit for adapting the voltage supplied to the gate of said enhanced-mode power transistor, said adaptation circuit comprising at least one branch connected between an input terminal adapted to receive a signal which could adopt a low state and a high state, and a second terminal, said at least one branch comprising:
a depletion-mode head transistor, the drain of which is connected to the input,
a depletion-mode tail transistor, the source of which is connected to a terminal of a first dipole, and the gate of which is connected to the second terminal of the first dipole,
a connecting quadrupole, the first terminal of which is connected to the gate of the head transistor, the second terminal of which is connected to the source of the head transistor, the third terminal of which is connected to the source of the tail transistor, and the fourth terminal of which is connected to the drain of the tail transistor, and
an enhanced-mode base transistor, the source of which is connected to the second terminal, and the gate of which is connected to its drain, said drain being connected to a second terminal of a second dipole, the first terminal of which is connected to the second terminal of the first dipole, said adaptation circuit being connected, by the source of the head transistor, to the gate of the power transistor.

2. Integrated circuit according to claim 1, wherein the connecting quadrupole is constituted of two short-circuits respectively connecting the first and third terminals and the second and fourth terminals.

3. Integrated circuit according to claim 1, wherein the connecting quadrupole comprises two depletion-mode transistors: a high transistor and a low transistor, the source of the high transistor being connected to the drain of the low transistor and to the first terminal of the connecting quadrupole, the drain of the high transistor being connected to the second terminal of the connecting quadrupole, the gate of the low transistor being connected to the third terminal of the connecting quadrupole and the gate of the high transistor and the source of the low transistor being connected to the fourth terminal of the connecting quadrupole.

4. Integrated circuit according to claim 1, wherein the connecting quadrupole is constituted of n elementary quadrupoles, with n>1, each elementary quadrupole comprising two depletion-mode transistors: a high transistor and a low transistor, the source of the high transistor being connected to the drain of the low transistor and to a first terminal of the elementary quadrupole, the drain of the high transistor being connected to a second terminal of the elementary quadrupole, the gate of the low transistor being connected to a third terminal of the elementary quadrupole and the gate of the high transistor and the source of the low transistor being connected to a fourth terminal of the elementary quadrupole; the elementary quadrupoles being connected in series, with two consecutive elementary quadrupoles connected such that the first terminal of the elementary quadrupole is connected to the third terminal of the elementary quadrupole and the second terminal of the elementary quadrupole is connected to the fourth terminal of the elementary quadrupole; the first and the second terminal of the elementary quadrupole forming the first and the second terminal of the connecting quadrupole and the third and the fourth terminal of the elementary quadrupole forming the third and the fourth terminal.

5. Integrated circuit according to claim 1, wherein the depletion-mode and enhanced-mode transistors are GaN transistors or MOS transistors.

6. Integrated circuit according to claim 1, wherein the first dipole is a resistor.

7. Integrated circuit according to claim 1, wherein the first dipole is an enhanced-mode transistor, the gate of which is connected to its drain.

8. Integrated circuit according to claim 2, wherein the second dipole is a short-circuit.

9. Integrated circuit according to claim 3, wherein the second dipole comprises an enhanced-mode transistor, the source of which is connected to the second terminal of the second dipole, and the gate of which is connected to its drain, said drain being connected to the first terminal of the second dipole.

10. Integrated circuit according to claim 4, wherein the second dipole comprises an enhanced-mode transistors, each of said transistors having its gate connected to its drain, said transistors being connected in series, two consecutive transistors being connected by the source of one and the drain of the other and, the drain of the first transistor forming the first terminal of the second dipole and the source of the last transistor forming the second terminal of the second dipole.

11. Integrated circuit according to claim 1, wherein the integrated circuit comprises an branches connected in parallel, each branch being connected by the source of its head transistor, to the gate of the power transistor.
